(19) United States
(12) Patent Application Publication
(10) Pub. No.: US 2004/0046544 A1
(43) Pub. Date: Mar. 11, 2004

(54) Inserting carriage for measuring and/or analytical device

(76) Inventor: Knut Hiltawski, Saalfeld (DE)

Correspondence Address: HOUSTON ELISEEVA, 4 MILITIA DRIVE, SUITE 4, LEXINGTON, MA, 02421, US

(21) Appl. No.: 10/433,288

(22) PCT Filed: Dec. 13, 2001
(86) PCT No.: PCT/DE01/04699

(30) Foreign Application Priority Data
Jan. 19, 2001 (DE) 101 02 541.6

(51) Int. Cl. G01R 1/00

(52) U.S. Cl. 324/158.1

(57) ABSTRACT

A measurement and/or analytical device (1) comprises a insertable trolley (2) which is insertable into an insertion opening and can be pulled completely out of the insertion opening. The insertable trolley (2) furthermore comprises sliding and/or rolling elements that are provided on a frame (6) in order to brace the latter in a vertical direction against a displacement surface, electrical and/or electronic control components for the measurement and/or analytical device (1) that are detachably mounted on the frame (6), and a flexible conductor bundle (8) for transferring control signals between the measurement and/or analytical device (1) and the control components.

Good accessibility to the control components of the measurement and/or analytical device (1) is thereby achieved in a compact design.

The invention concerns the field of measurement and/or analytical technology as well as corresponding devices.

Measurement and/or analytical devices generally comprise a plurality of control components that can be arranged in the vicinity of the associated functional components. Often the control components are also centrally combined together at a common location, for example in an electrical cabinet. In the case of stationary devices, an electrical cabinet of this kind can be set up separately from the relevant measurement and/or analytical device. The advantage of this is that the individual control components, in particular electrical and electronic units and plug-in and insertable boards and modules, are easily accessible. Usually, however, such electrical cabinets are accessible from only one side, so that they require a relatively large amount of space.

In particular when the installation location of the measurement and/or analytical device needs to be changed frequently, it is necessary to arrange the control components directly on the measurement and/or analytical device. As far as a compact design is concerned, the aforesaid electrical cabinets are no longer suitable for this purpose. Instead it is desirable to group the control components together as closely as possible. In practice, however, this entails considerable difficulties regarding the accessibility of the control components, in particular when repairs or maintenance on the control components are necessary.

The use of plug-in boards and insertable units may represent a suitable solution for individual components in individual cases, but is not practical for a larger number of control components.

Proceeding from this existing art, it is the object of the invention to create, in the context of a measurement and/or analytical device, a good capability for access to its control components.

This object is achieved for a measurement and/or analytical device, in particular one for the microscopic viewing of semiconductor wafers, having a insertion opening and a insertable trolley which comprises:

a frame that can be inserted into the insertion opening and can be pulled completely out of the insertion opening;

sliding and/or rolling elements that are provided on the frame in order to brace the latter in a vertical direction against a displacement surface;

electrical and/or electronic control components for the measurement and/or analytical device that are detachably mounted on the frame; and

means for transferring control signals between the measurement and/or analytical device and the control components.

The solution according to the present invention allows a large number of control components, or even all the control components, of a measurement and/or analytical device to be arranged very compactly in a module of restricted size that, in a service context, can easily be pulled out of the insertion opening. Since the frame of the insertable trolley can be pulled completely out of the insertion opening, the control components can in turn be arranged without restriction-on the frame. The manner in which the individual components are mounted can correspond to that in conventional electrical cabinets, except that there is greater flexibility in terms of arrangement. The fact that the insertable trolley is completely pulled out moreover allows very free access to the control components, since frames in the pulled-out state can be approached from all sides, or at any rate from two opposite sides.

The transfer of control signals can, in principle, be accomplished wirelessly. In an advantageous embodiment of the invention, however, a flexible conductor bundle that connects the control components to the measurement and/or analytical device is provided. Large data volumes, in particular, can be transferred at high speed over the conductor bundle. The flexibility of the conductor bundle ensures that the frame can be pulled far enough out of the insertion opening.

In order to prevent damage to the conductor bundle, it is advantageous to provide a pullout limiter between the frame and the measurement and/or analytical device.

The pullout limiter comprises, for example, a foldable articulated arm. The latter on the one hand ensures sufficient strength to prevent detachment of the conductor bundle when the insertable trolley is pulled completely out. On the other hand, the foldable articulated arm requires little space when collapsed, so that the insertion opening does not need to be made much larger than the frame.

In accordance with a further embodiment of the invention, it is additionally advantageous in this context to mount the articulated arm on the back side of the frame, which is the first to be inserted into the insertion opening. It is thereby possible, in particular, to eliminate the risk of crushing the sensitive conductor bundle.

The articulated arm preferably comprises several arm segments that can be collapsed flat and are joined together articulatedly at their ends in the manner of a chain. An articulated arm of this kind can be collapsed in very compact fashion like a bellows.

In principle, it is possible to arrange the flexible conductor bundle for the transfer of control signals separately from the articulated arm. To prevent crushing or other damage to the conductor bundle while the insertable trolley is being pulled out or inserted, in a further advantageous embodiment of the invention the flexible conductor bundle is arranged so as to extend in the articulated arm. For this purpose, the individual arm segments of the articulated arm are configured sufficiently stiffly that it constitutes a self-supporting structure which can be collapsed and unfolded in a predefined manner.

In addition to the control components, other electrical and electronic power components can, also be detachably mounted on the frame. A flexible conductor bundle is then additionally provided between the power components and the measurement and/or analytical device. This further conductor bundle can be guided together with the conductor bundle for the control signals. To prevent any impairment of the control signals, however, it is advantageous to shield the conductor bundle or to guide the conductor bundle for power transfer separately. Also possible here is the use of an additional articulated arm for the conductor bundle for power transfer, which can be configured in the manner described above.

In a further advantageous embodiment of the invention, an operating console for operation of the measurement and/or analytical device, which coacts with the control components and is freely accessible to an operator even when the frame is in the inserted state, is provided on the frame. Serviceability and access to the control components is thereby further facilitated, since when the insertable trolley is pulled out, the operating console remains connected to the control components and the measurement and/or analytical device remains ready to operate, thus also eliminating the need for a detachable interface between the operating console and the control components.

To facilitate actuation of the operating console, which can comprise a plurality of actuation elements and indicating devices, an open space down to the displacement surface is provided under the operating console. An operator can thus approach closer to the operating console, or can work while sitting comfortably in front of it.

In a further advantageous embodiment of the invention, guide elements that, upon insertion into the insertion opening, coact with guide elements on the measurement and analytical device are provided on the sides of the frame. It is thereby possible to prevent, upon insertion, jamming of the insertable trolley or, in some circumstances, damage to parts of the measurement and/or analytical device, even though the insertion openings closely surround the insertable trolley. The guide elements on the frame are configured, for example, as rollers that rotate about an axis perpendicular to the displacement surface. The displacement resistance as the insertable trolley is inserted and pulled out thus remains low.

The invention will be-explained in more detail below with reference to two exemplary embodiments. In the accompanying drawings:

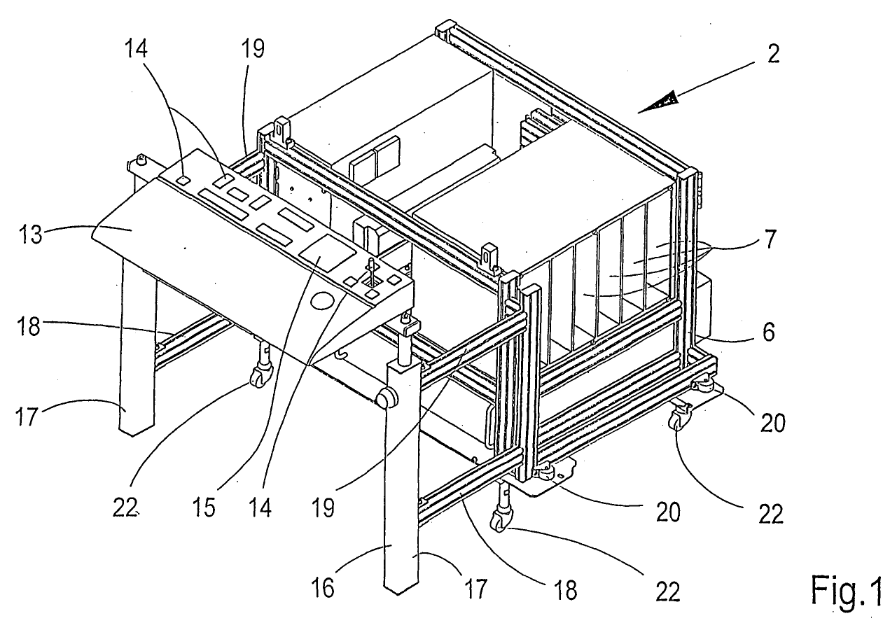

FIG. 1 is a perspective view of a first exemplary embodiment of a insertable trolley according to the invention;

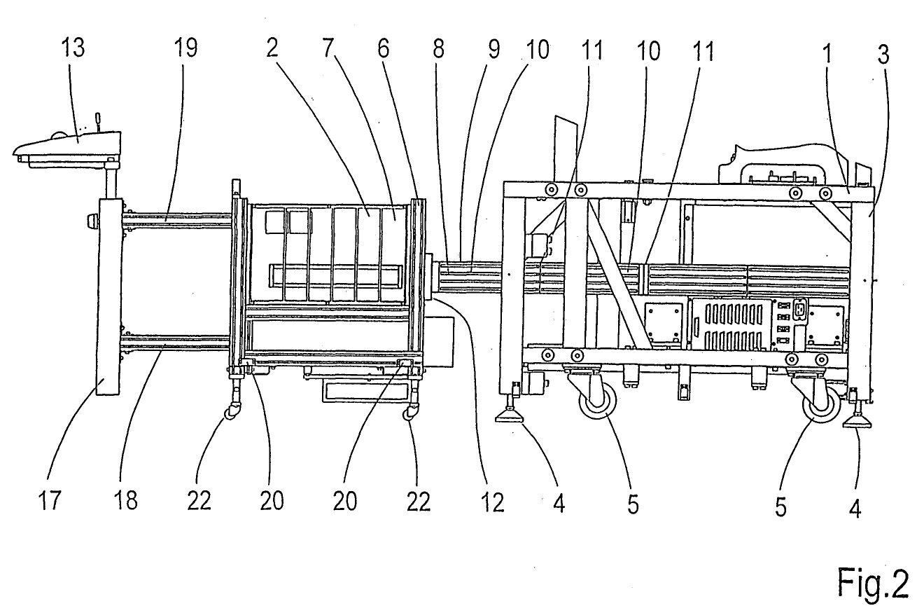

FIG. 2 is a side view of the insertable trolley of the first example together with a base portion of a measurement and/or analytical device, the insertable trolley being shown in a pulled-out state;

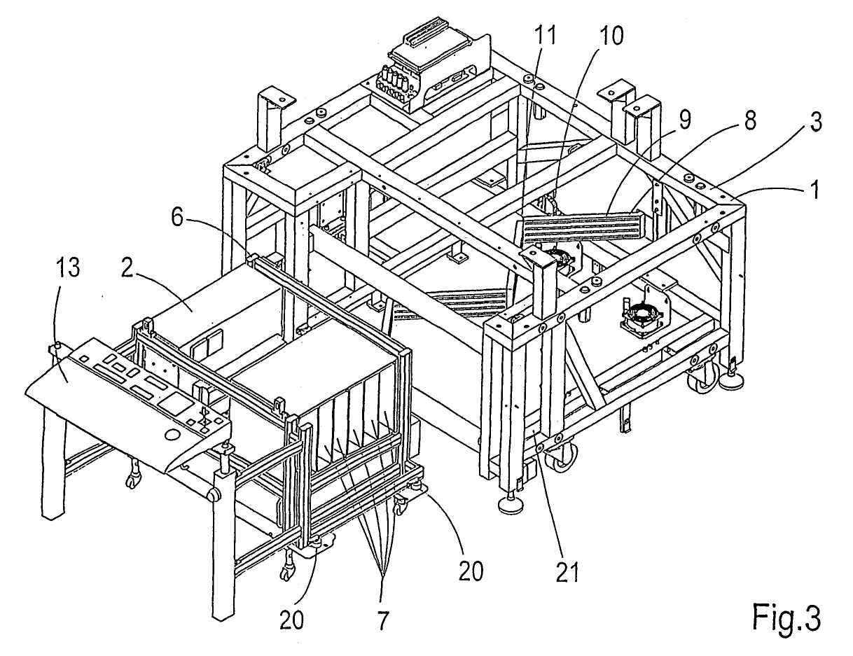

FIG. 3 shows the insertable trolley and the measurement and/or analytical device in the position of FIG. 2, in a perspective view;

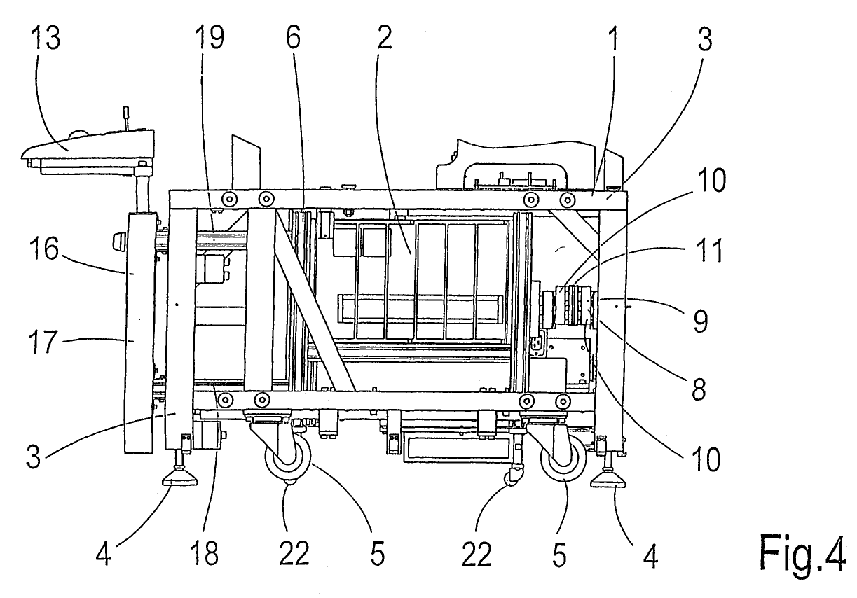

FIG. 4 shows the insertable trolley in a state maximally inserted into the measurement and/or analytical device, in a side view;

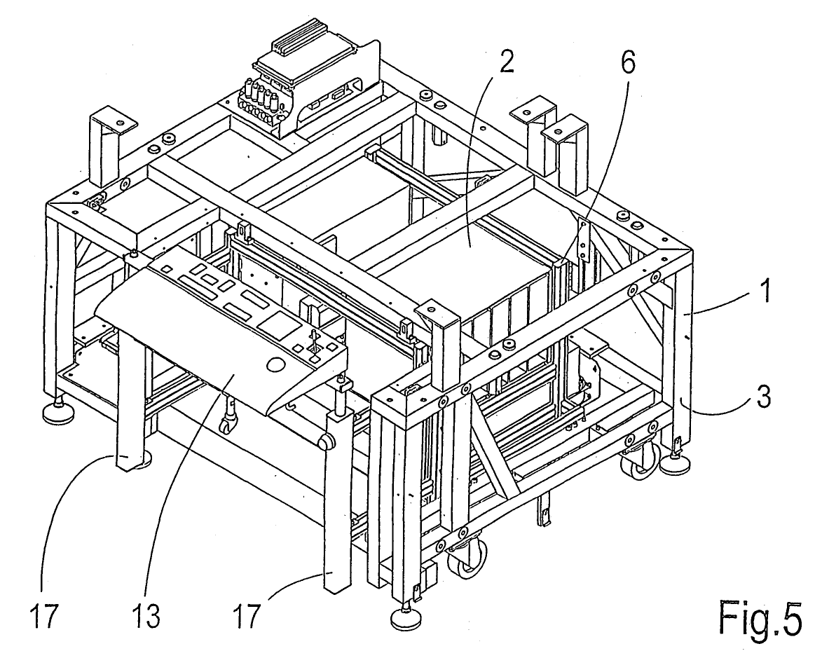

FIG. 5 is a perspective view of the insertable trolley and the measurement and/or analytical device, with the insertable trolley in the maximally inserted state; and

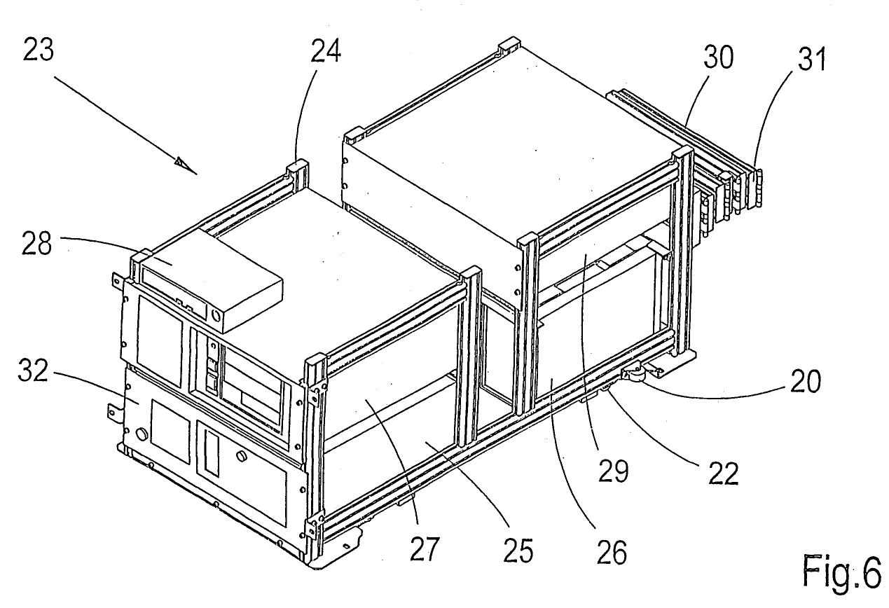

FIG. 6 shows a further example of a insertable trolley, in a view corresponding to FIG. 1.

The first exemplary embodiment according to FIGS. 1 through 5 shows a measurement and analytical device 1 having an insertable trolley 2. Measurement and analytical device 1, only a base portion of which is depicted here, is configured as an inspection device for the microscopic examination of semiconductor wafers. The base portion comprises a frame 3 made up of a plurality of struts that are assembled in a manner of a skeleton structure. Frame 3 is supported by way of support feet 4 on a floor that also serves as a displacement surface for insertable trolley 2.

Also mounted on frame 3 are several wheels 5 with which, after frame 3 is lowered, measurement and analytical device 1 can be displaced. Support feet 4 are pulled in for that purpose. In a modified construction, however, it is also possible to design wheels 5 so they can extend downward.

Provided on frame 3 of measurement and analytical device 1 is an insertion opening which is open on one side toward the installation surface of measurement and analytical device 1 (i.e. open toward the bottom), and into which insertable trolley 2 can be inserted so that the latter is to a very large extent received in frame 3.

Said insertable trolley 2 will now be explained in greater detail. As FIG. 1 shows, insertable trolley 2 comprises a frame 6 that is configured as a skeleton construction 6 and comprises a plurality of receiving spaces 7 for control components (not depicted in more detail in FIG. 1) of measurement and analytical device 1. The control components, for example electrical and/or electronic devices and plug-in or insertable modules or boards, are introduced into receiving spaces 7 and are thus detachably connected to frame 6. Suitable transfer means are provided for the transfer of control signals between the control components and measurement and analysis device 1. In the exemplary embodiment depicted, these are a flexible conductor bundle 8.

In order to prevent damage to conductor bundle 8, a pullout limiter coordinated with the length of flexible conductor bundle 8 is provided between insertable trolley 2 and measurement and analytical device 1. FIG. 2 and FIG. 3 show the pullout limiter in a partially pulled-out state, in which insertable trolley 2 with its frame is outside the insertion opening of frame 3 of the measurement and analytical device and is relatively freely movable. The pullout limiter is configured, by way of example, as a foldable articulated arm 9 that comprises a plurality of (here, a total of four) arm segments 10 that are joined to one another in pairs at their ends via respective joints 11. The individual arm segments 10 support one another and are mounted on the one hand in the housing of the measurement and analytical device and on the other hand on the frame of insertable trolley 2, and because of their articulated connection to one another can be collapsed into a flat packet, as depicted in FIG. 4 which shows insertable trolley 2 maximally inserted into the insertion opening.

The pullout limiter, which adjoins back side 12 of insertable trolley 2 and its frame 6, serves at the same time to receive conductor bundle 8 for the control signals. For that purpose, the individual conductors of conductor bundle 8 are integrated, for example embedded, into articulated arm 9. It is also possible to guide conductor bundle 8 loosely inside articulated arm 9, for which purpose the individual elements of articulated arm 9 are of correspondingly hollow configuration. Conductor bundle 8 can also be mounted externally on articulated arm 9.

Instead of articulated arm 9, it is also possible, for example, to use as flexible conductor bundle 8 a multi-strand ribbon cable that itself possesses a certain tensile strength and thus also assumes the function of the pullout limiter. In such a case, however, the connectors on measurement and analytical device 1 and on the insertable trolley are additionally protected against detachment by means of strain reliefs. It is furthermore possible to provide a plug-in connection between back side 12 of insertable trolley 2 and conductor bundle 8, so that insertable trolley 2 can easily be uncoupled from conductor bundle 8. This is also applicable if conductor cable 8 is integrated into articulated arm 9.

In addition to the control components, power components of measurement and analytical device 1 can also be provided on frame 6 of insertable trolley 2. Connection thereof to measurement and analytical device 1 is preferably accomplished via a separate power bundle for power transfer which is not, however, depicted in greater detail in the drawings. This additional power bundle can be configured in the same manner as the one for the control signals, although the conductor cross sections must be adapted to the higher power level.

By shielding the conductor bundle for the control signals it is also possible to combine the two conductor bundles with one another, for example to integrate them into the same articulated arm 9.

Also provided on frame 6 of insertable trolley 2 is an operating console 13 that comprises a plurality of operating elements 14 and indicating devices 15. The manner of operation of measurement and analytical device 1 can be influenced via operating console 13, which is linked to the control components on frame 6.

Operating console 13 is mounted on a frontal structure 16 of insertable trolley 2 that in turn is joined to frame 6. Frontal structure 16 comprises two vertical columns 17 on which operating console 13 is braced, preferably adjustably as to height and removably. Columns 17 are arranged, spaced apart from one another in the width direction of insertable trolley 2, on the two sides of insertable trolley 2, and are joined, each via two longitudinal members 18 and 19, to frame 6. An open space thus remains beneath operating console 13, making it possible to work in seated fashion in front of operating console 13. The foot and knee room left open, and the, adjustability of operating console 13 as to height, result in a workplace that is favorable from an ergonomic point of view, in particular even-when insertable trolley 2 is inserted into measurement and analytical device 1. This actual operating position of the entire arrangement is shown in FIG. 4 and FIG. 5.

In order to prevent jamming upon insertion of insertable trolley 2 into the insertion opening or also upon withdrawal thereof from the insertion opening, guide elements which coact with guide elements provided on frame 3 of measurement and analytical device 1 are provided on frame 6 of insertable trolley 2. In the example depicted here, the guide elements on frame 6 are configured as rollers 20 whose rotation axes extend perpendicular to the installation surface of measurement and analytical device and the displacement surface of insertable trolley 2. As insertable trolley 2 is inserted into or taken out of the insertion opening, said rollers 20 run on guide rails 21 of measurement and analytical device 1.

To make insertable trolley 2 easier to move, frame 6 is supported on wheels 22. Other rolling elements or sliding elements which facilitate maneuverability on the installation surface of measurement and analytical device 1, which here simultaneously represents the displacement surface of insertable trolley 2, can also be utilized instead of said wheels 22.

In the first exemplary embodiment depicted, frame 6 of insertable trolley 2 can be pulled completely out of the insertion opening of measurement and analytical device 1, specifically in such a fashion that in the pulled-out state it is accessible from all sides. Receiving spaces 7 for the control components, and any power components, accordingly can in turn be arranged in very compact fashion. Despite this compact arrangement, each individual component remains very easily accessible when necessary. All that is required for that purpose is to pull insertable trolley 2, which with its frame 6 is received completely in measurement and analytical device 1, out of the latter's insertion opening. In particular, doing so does not require removal of any panels, covers, or the like, or disconnection of electrical elements such as, for example, operating console 13.

The arrangement of control and power components on frame 6 of insertable trolley 2 can be selected relatively freely, as is illustrated with reference to the second exemplary embodiment in FIG. 6. The latter shows a further insertable trolley 23 that can be inserted, instead of insertable trolley 2 of the first exemplary embodiment, into measurement and analytical device 1 depicted in FIG. 2 through FIG. 5. Insertable trolley 23 in turn comprises a frame 24 on which multiple control components 25 through 29 are detachably mounted. The transfer of control signals between said control components 25 through 29 and measurement and analytical device 1 is accomplished via a conductor bundle 30 that is integrated into an articulated arm 31. Conductor bundle 30 and articulated arm 31 can be configured as already described in conjunction with the first exemplary embodiment. Here as well, in similar fashion, power components can additionally be mounted detachably on frame 24.

In contrast to the first exemplary embodiment, the desk-like operating console 13 can also be omitted and replaced by an integrated operating console 32. The latter remains externally accessible even with insertable trolley 23 in the maximally inserted state.

Insertable trolley 23 of the second exemplary embodiment can also be pulled completely out of the insertion opening and, because of the articulated nature of its attachment to measurement and analytical device 1, rotated in front of the latter for better accessibility.

### Parts List

1 Measurement and/or analytical device

2 Insertable trolley

3 Frame of measurement and/or analytical device

4 Support foot

5 Wheel

6 Frame of insertable trolley

7 Receiving space

8 Conductor bundle

9 Articulated arm

10 Arm segment

11 Joint

12 Back side

13 Operating console

14 Actuation element

15 Display element

16 Frontal structure

17 Column

18 Longitudinal strut

19 Longitudinal strut

20 Roller

21 Guide rail

22 Wheel

23 Insertable trolley

24 Frame

25-29 Control components

30 Conductor bundle

31 Articulated arm

32 Operating console

1. A measurement and/or analytical device, in particular for the microscopic viewing of semiconductor wafers, having a insertion opening and a insertable trolley which comprises:
a frame (6) that can be inserted into the insertion opening and can be pulled completely out of the insertion opening;
sliding and/or rolling elements that are provided on the frame (6) in order to brace the latter in a vertical direction against a displacement surface;
electrical and/or electronic control components for the measurement and/or analytical device (1) that are detachably mounted on the frame (6); and
means for transferring control signals between the measurement and/or analytical device (1) and the control components.

2. The measurement and/or analytical device as defined in claim 1, wherein a flexible conductor bundle (8) is provided as the means for transferring the control signals.

3. The measurement and/or analytical device as defined in claim 1 or 2, wherein a pullout limiter is provided on the frame (6).

4. The measurement and/or analytical device as defined in claim 3, wherein the pullout limiter comprises at least one foldable articulated arm (9).

5. The measurement and/or analytical device as defined in claim 4, wherein the articulated arm (9) is mounted on the back side (12) of the frame (6), which is the first to be inserted into the insertion opening.

6. The measurement and/or analytical device as defined in claim 4 or 5, wherein the articulated arm (9) comprises several arm segments (10) that can be collapsed flat and are joined together articulatedly at their ends.

7. The measurement and/or analytical device as defined in one of claims 4 through 6, wherein the flexible conductor bundle (8) extends in the articulated arm (9).

8. The measurement and/or analytical device as defined in one of the foregoing claims, wherein electrical and/or electronic power components are also detachably mounted on the frame (6), and a flexible conductor bundle is provided between the power components and the measurement and/or analytical device (1) for power transfer.

9. The measurement and/or analytical device as defined in one of the foregoing claims, wherein an operating console (13) for operation of the measurement and/or analytical device (1) is provided on the frame (6), the operating console (13) coacting with the control components and being freely accessible from the outside when the frame (6) is in the inserted state into the insertion opening.

10. The measurement and/or analytical device as defined in claim 9, wherein an open space extending down to the height of the displacement surface is provided under the operating console (13).

11. The measurement and/or analytical device as defined in one of the foregoing claims, wherein guide elements that, upon insertion into the insertion opening, coact with guide elements on the measurement and analytical device (1) are provided on the sides of the frame (6).

12. The measurement and/or analytical device as defined in claim 11, wherein the guide elements on the frame (6) are configured as rollers (20) that are mounted rotatably about an axis perpendicular to the displacement surface.
